(19) United States
(12) Patent Application Publication
(10) Pub. No.: US 2023/0387349 A1
(43) Pub. Date: Nov. 30, 2023

(54) COMBINED EPITAXIAL GROWTH SYSTEM HAVING MULTIPLE REACTION CHAMBERS, OPERATION METHOD, DEVICE, AND MANUFACTURED CHIP AND APPLICATION THEREOF

(71) Applicant: FOSHAN UNIVERSITY, Foshan (CN)

(72) Inventors: Bingfeng Fan, Foshan City (CN); Zekai Hong, Foshan City (CN)

(21) Appl. No.: 17/798,480

(22) PCT Filed: Oct. 30, 2020
(86) PCT No.: PCT/CN2020/125364

§ 371 Date: Aug. 9, 2022

(30) Foreign Application Priority Data
Sep. 18, 2020 (CN) 202010988009.3

(51) Int. Cl. H01L 33/32; H01L 25/075; H01L 33/00; C23C 16/30

(52) U.S. Cl. CPC H01L 33/32; H01L 25/0753; H01L 33/007; C23C 16/303

(57) ABSTRACT

The present disclosure provides a combined epitaxial growth system having multiple reaction chambers, an operation method, a device, and a manufactured chip and an application thereof. With a special metal-organic chemical vapor deposition (MOCVD) machine, a group III-V compound epi-wafer and a group II-VI compound epi-wafer are sequentially grown on a substrate. A time interval a at which multiple group III-V compound reaction chambers are sequentially started is the same as growth time y of the group II-VI compound epi-wafer. With the multi-chamber and stepwise manner, not only are a group III-V compound and a group II-VI compound deposited in the reaction chambers more effectively, but the time division multiplexing (TDM), effective integration of the stepwise process, and capacity matching are also implemented. The present disclosure further provides a combined epitaxial growth device having multiple reaction chambers, including a first growth device, a feeding device and a second growth device.

### CROSS REFERENCE TO RELATED APPLICATION

This patent application claims the benefit and priority of Chinese Patent Application No. 202010988009.3, filed on Sep. 18, 2020, the disclosure of which is incorporated by reference herein in its entirety as part of the present application.

### TECHNICAL FIELD

The present disclosure belongs to the technical field of semiconductor material preparation, and in particular to a combined epitaxial growth system having multiple reaction chambers, an operation method, a device, and a manufactured chip and an application thereof.

### BACKGROUND ART

Group II-VI compound epi-wafers (such as transparent zinc oxide (ZnO) electrode thin films) are transparent over a wavelength range of 400 nm to 2 μm, and thus can be used to manufacture transparent electrodes. By doping a trace of Al, Ga and the like to group II-VI compounds, high-quality group II-VI compound thin films with low resistances and high transmittances can be obtained, and can be used as current spreading layers. Transparent group II-VI compound electrode thin films are further praised as preferred transparent electrode materials instead of indium tin oxide (ITO) materials, because they are non-toxic, cost-effective, environment-friendly and relatively stable at high temperatures.

Metal-organic chemical vapor deposition (MOCVD) is considered as a key to preparation of compound semiconductor films. It is implemented by taking volatile organic matters like (C₂H₅)₂Zn as source reactants of involatile metal atoms, carrying the organic matters to a reactor through a carrier gas to react with O₂ and H₂O, and growing group II-VI compound epi-wafers (such as transparent ZnO electrode thin films) on heated substrates, and has been applied to microelectronic devices or photoelectric devices. According to the specific use, existing MOCVD mechanical devices can be divided into MOCVD devices for processing GaN thin films, MOCVD devices for processing ZnO thin films, etc.

Existing blue light-emitting diode (LED) chips are obtained by preparing group III-V compound epi-wafers on the substrates, and then growing group II-VI compound epi-wafers thereon. However, the existing preparation process is implemented stepwise. For the design and manufacture of mainstream MOCVD devices on existing markets, the epi-wafers are placed into the furnace and taken out of the furnace manually for two times or more in each complete round of production for the LED chips. As a result, the growth efficiency of the products is seriously restricted, there is a big difference in the growth atmosphere between nitride MOCVD (reducing atmosphere) and oxide MOCVD (oxidizing atmosphere) during integration, and problems such as capacity matching occur. The preparation time (which is 6-7 h usually and is specifically determined by the actual process) of the group III-V compound epi-wafers is longer than the growth time (which is 2 h usually and is specifically determined by the actual process) of the group II-VI compound epi-wafers, which increases the time and other costs, impairs the production efficiency, and violates concepts of the modern automation, environmental protection and energy conservation. In addition, in view of no multifunctional MOCVD machine at present, materials or thin films of different layers are still prepared stepwise with individual MOCVD machines corresponding to different functions.

However, when processing different functional materials or thin films, the individual MOCVD machines used are structurally similar in fact. For the problems such as the capacity matching, multiple MOCVD machines for preparing group III-V compound epi-wafers may be cooperatively used with a single MOCVD machine for preparing group II-VI compound epi-wafers, thereby manufacturing the blue LED chips. In this way, there are many MOCVD machines, which undoubtedly increases the device cost, presents the huge upfront cost and intangible pressure to production, and also violates the concepts of the modern automation, environmental protection and energy conservation.

Therefore, how to implement effective integration and effective capacity matching with the stepwise process is a technical problem to be solved urgently at present.

### SUMMARY

The present disclosure provides a combined epitaxial growth system having multiple reaction chambers, an operation method, a device, and a manufactured chip and an application thereof, to solve one or more technical problems in the prior art, and provide at least one beneficial choice or condition.

To overcome the above technical problems, the present disclosure adopts the following technical solutions:

The present disclosure provides a combined epitaxial growth system having multiple reaction chambers, including:

a first growth device, where the first growth device is an MOCVD machine for preparing a group III-V compound, multiple group III-V compound reaction chambers are formed in the MOCVD machine, and the group III-V compound reaction chambers each are configured to prepare a group III-V compound epi-wafer;

a second growth device, where the second growth device is an MOCVD machine for preparing a group II-VI compound, a group II-VI compound reaction chamber is formed in the MOCVD machine, and the group II-VI compound reaction chamber is configured to prepare a group II-VI compound epi-wafer; and

a feeding device,

where the multiple group III-V compound reaction chambers are sequentially started in terms of a same time interval; and assuming that the time interval is a, a>0, the group III-V compound epi-wafer has growth time of x, x>0, and the group II-VI compound epi-wafer has growth time of y, y>0, there is a need to satisfy a=y.

As a further improvement to the above solution, the second growth device may be replaced with an MOCVD machine for preparing a group III-VI compound, and a group III-VI compound reaction chamber may be formed in the MOCVD machine and configured to prepare a group III-VI compound epi-wafer.

As a further improvement to the above solution, there may be one group II-VI compound reaction chamber. Based on the group II-VI compound reaction chamber, the multiple group III-V compound reaction chambers sequentially started are used cooperatively with the group II-VI compound reaction chamber, such that the group II-VI compound epi-wafer can be continuously produced in the group II-VI compound reaction chamber. With time division multiplexing (TDM) on the group II-VI compound reaction chamber, the whole continuous production and the maximum utilization of the group II-VI compound reaction chamber are ensured.

The present disclosure provides an operation method of the combined epitaxial growth system having multiple reaction chambers, which assumes that there are n group III-V compound reaction chambers, n being an integer greater than 0, and includes the following steps:
1) preparing group III-VI compound epi-wafers: taking substrates, placing the substrates into the group III-V compound reaction chambers respectively, assuming that i has an initial value of 1, a value of the i being in a range of [1, n], starting an ith group III-V compound reaction chamber, and starting the ith group III-V compound reaction chamber after a period of at least (i−1)y, thereby obtaining group III-V compound epi-wafers on surfaces of the substrates in all of the group III-V compound reaction chambers;
2) starting the feeding device, increasing the value of the i by 1, and transferring a group III-V compound epi-wafer in the ith group III-V compound reaction chamber to the group II-VI compound reaction chamber in the second growth device after a period of at least x+(i−1)y;
3) preparing a chip: starting the group II-VI compound reaction chamber, and obtaining, after a period of at least x+iy, a chip with a group II-VI compound epi-wafer covering a surface of the group III-V compound epi-wafer;
4) removing the chip from the group II-VI compound reaction chamber, and supplementing a substrate to the vacant group III-V compound reaction chamber; and
5) going back to step 2) if inn, and setting the value of the i as 1 and going back to step 2) if i=n; or ending a reaction if group III-VI compound epi-wafers generated in remaining group III-V compound reaction chambers are all transferred to the group II-VI compound reaction chamber sequentially to obtain the chip.

As a further improvement to the above solution, the number n of the group III-V compound reaction chambers, the x and the y satisfy: n=x/y if a value of x/y is a positive integer; and n=x/y and the value of the n is obtained by rounding up if the value of x/y is not the positive integer.

It is to be noted that when processing and preparing materials or thin films of different layers, individual MOCVD machines corresponding to different functions, namely special machines for special purposes, are still necessary at present, which is unavoidable for the production design of the individual MOCVD machines.

Semi-finished group III-V compound epi-wafers obtained in the group III-V compound reaction chambers are sequentially placed into the group II-VI compound reaction chamber for preparing the group II-VI compound epi-wafer. Upon completion of the former group II-VI compound epi-wafer, a next group II-VI compound epi-wafer is produced in the reaction chamber. In this way, the total time required to process a batch of group III-V compound epi-wafers is approximately the same as that required to process the group II-VI compound epi-wafers for the batch of group III-V compound epi-wafers. Therefore, the present disclosure can combine and regulate the production according to the time for preparing the group III-V compound epi-wafers and the time for preparing the group II-VI compound epi-wafers, and selects the MOCVD machine suitable for the production scale, thereby reducing the stop time of the MOCVD machine, ensuring the continuous production and the maximum utilization of the MOCVD machine and the reaction chambers, and realizing the continuous “seamless” production to the greatest extent.

Further, the group III-V compound epi-wafer may be made of a group III-V compound selected from one of a group consisting of BN, BP, Bas, BSb, AlN, AlP, AlAs, AlSb, GaN, GaP, GaAs, GaSb, InAs, InN, InP or InSb, or a ternary or quaternary material composed of three or four elements in the above materials, and preferably GaN, GaAs or InP.

The group III-V compound may refer to a compound formed by B, Al, Ga, and In in a group III and N, P, As, and Sb in a group V in a periodic table of elements. The group III-V compound may have an expression of A(III)B(V), such as BN, BP, Bas, BSb, AlN, AlP, AlAs, AlSb, GaN, GaP, GaAs, GaSb, InAs, InN, InP and InSb, where BN, AlN, GaN and InN may be of a wurtzite structure, and remaining twelve expression may be of a zinc-blende structure. A group III-V compound semiconductor material may refer to a compound semiconductor material formed by an element in the group III and an element in the group V in the periodic table of elements.

Further, the group II-VI compound epi-wafer may be made of a group II-VI compound selected from one of a group consisting of ZnS, ZnSe, ZnO, ZnTe, CdS, CdSe, CdTe, HgS, HgSe or HgTe, or a ternary or quaternary material composed of three or four elements in the above materials, and preferably ZnO or Ga₂O₃. The group II-VI compound may refer to a compound formed by Zn, Cd, and Hg in a group II and O, S, Se, and Te in a group VI in the periodic table of elements; and the group II-VI compound may have an expression of A(II)B(VI), such as ZnS, ZnSe, ZnO, ZnTe, CdS, CdSe, CdTe, HgS, HgSe and HgTe.

A group II-VI compound semiconductor material may refer to a compound semiconductor material formed by an element in the group II and an element in the group VI in the periodic table of elements. With the wide variation range of the bandgap, and direct-transition band structure, the group II-VI compound semiconductor material has been widely applied to solid-state light-emitting devices, laser devices, infrared devices, piezoelectric devices, etc. Particularly, ZnO semiconductor materials show the outstanding performance.

Further, the group III-VI compound epi-wafer may be made of a group III-VI compound selected from one of a group consisting of Al₂O₃, Ga₂O₃ and In₂O₃, and preferably Ga₂O₃.

Further, a tray for placing the substrate and a related product may be provided in each of the group II-VI compound reaction chamber and the group III-V compound reaction chamber; and the tray may be preferably a graphite tray.

Further, an actuator arm for transferring the tray may be provided in the feeding box; and the actuator arm may move in a space without a dead angle.

As a further improvement to the above solution, a tray may be provided in each of the group II-VI compound reaction chamber and the group III-V compound reaction chamber; the tray may be preferably a graphite tray; and the operation method may further include an annealing step with furnace annealing and a P-type annealing furnace between step 1) and step 3), a step of preheating the group II-VI compound reaction chamber before starting the group II-VI compound reaction chamber in step 3), a step of baking the tray between step 3) and step 4), and a step of suspending operation between step 4) and step 5) for a period which may be greater than 0 and may be preferably 1 h.

The annealing furnace is intended to eliminate the residual stress of the group III-V compound epi-wafer, reduce the deformation and cracking of the epi-wafer, refine the granularity, regulate the structure and remove the structural defects. The growth time of the group II-VI compound epi-wafer=preheating time+actual growth time of the group II-VI compound epi-wafer.

Further, the annealing furnace, the tray baking furnace, the group II-VI compound reaction chamber, and the group III-V compound reaction chamber may be provided at the periphery of the feeding box, so as to facilitate feeding of the actuator arm.

The present disclosure provides a combined epitaxial growth device having multiple reaction chambers, including:

a first growth device, where the first growth device is an MOCVD machine for preparing a group III-V compound, and multiple group III-V compound reaction chambers are formed in the MOCVD machine and configured to prepare a group III-V compound epi-wafer respectively;

a second growth device, where the second growth device is an MOCVD machine for preparing a group II-VI compound, and a group II-VI compound reaction chamber is formed in the MOCVD machine and configured to prepare a group II-VI compound epi-wafer; and

a feeding device, where the feeding device is a feeding box, and an actuator arm is provided in the feeding device.

The present disclosure provides a chip, which is manufactured with the operation method.

As a further improvement to the above solution, the chip may be of a layered structure, sequentially including a substrate layer, a first laminated layer and a second laminated layer; the substrate layer may include a substrate; the first laminated layer may include the group III-V compound epi-wafer; and the second laminated layer may include either the group III-V compound epi-wafer or the group II-VI compound epi-wafer.

The present disclosure provides an application of the chip in preparing an LED.

The present disclosure has the following beneficial effects:
(1) The present disclosure provides a combined epitaxial growth system having multiple reaction chambers and an operation method thereof. With a special MOCVD machine, a group III-V compound epi-wafer and a group II-VI compound epi-wafer are sequentially grown on a substrate. A time interval a at which multiple group III-V compound reaction chambers are sequentially started is the same as growth time y of the group II-VI compound epi-wafer. With the multi-chamber and stepwise manner, not only are a group III-V compound and a group II-VI compound deposited in the reaction chambers more effectively, but the TDM, effective integration of the stepwise process, and effective capacity matching are also implemented.
(2) The present disclosure further provides a combined epitaxial growth device having multiple reaction chambers, including a first growth device, a feeding device and a second growth device. An actuator arm is provided in the feeding device. The combined epitaxial growth device is designed reasonably, which can greatly reduce the device cost and the time, ensures the continuous production, and achieves the maximum utilization of the MOCVD machine and the reaction chambers.
(3) The present disclosure further manufactures a chip. The surface of the chip is under balanced force with no or little cracks, controllable thickness and clear layering, and the multiquantum well (MQW) structure, ohmic contact and tunnel junction are provided in the thin film. Therefore, the chip is applied to preparation of the LED and has the wide application prospect.

### BRIEF DESCRIPTION OF THE DRAWINGS

In order to more clearly illustrate the technical solutions in the embodiments of the present disclosure, a brief introduction to the accompanying drawings required for the embodiments will be provided below. Apparently, the described embodiments are merely a part rather than all of the embodiments of the present disclosure. Those skilled in the art can obtain other solutions and drawings based on these drawings without creative efforts.

FIG. 1 is a schematic structural view of a gallium nitride (GaN)-based ZnO chip;

FIG. 2 is a schematic view illustrating combined epitaxial growth for GaN and ZnO compounds in Embodiment 1;

FIG. 3 is a schematic structural view of an actuator arm in a feeding box; and

FIG. 4 is a capacity matching map in Embodiment 1.

### DETAILED DESCRIPTION OF THE EMBODIMENTS

The present disclosure will be described below in detail with reference to the embodiments, so as to facilitate understanding of those skilled in the art to the present disclosure. It is to be noted that the embodiments are merely used to further illustrate the present disclosure, rather than limit the protection scope of the present disclosure. Any unessential improvement and adjustment made to the present disclosure according to the contents of the present disclosure should be included in the protection scope of the present disclosure. Furthermore, any raw materials not described below in detail are all commercially available products. Any steps or extracting methods not described in detail are all steps or extracting methods known to those skilled in the art.

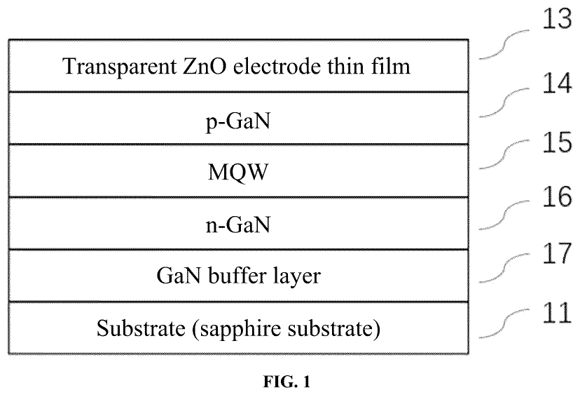

FIG. 1 is a schematic structural view of a GaN-based ZnO chip. As shown in FIG. 1, the GaN-based ZnO chip in the LED structure 12 is manufactured on a clean substrate 11 (sapphire substrate). A GaN buffer layer 17 is deposited on the substrate 11, and is deposited in a GaN reaction chamber 2 by an MOCVD process at 500-600° C. for about 5 min. An n-GaN layer 16 is deposited on the GaN buffer layer 17. The n-GaN layer 16 is usually deposited at 1,000-1,100° C., with a specific thickness determined by the time. An MQW layer 15 is deposited on the n-GaN layer 16 at about 750-950° C., with a specific thickness determined by the time. A p-GaN layer 14 is deposited on the MQW layer 15. The p-GaN layer 14 serves as a contact layer, and is deposited at 1,000-1,100° C., with a specific thickness determined by the time. Till now, the epitaxial growth of the GaN epi-wafer has been completed. The obtained GaN epi-wafer is transferred to a ZnO reaction chamber to grow a ZnO thin film. A transparent ZnO electrode thin film is deposited on the p-GaN layer 14.

Further, the present disclosure can further regulate the performance of the epitaxial material by introducing a doping element such as Si and Mg. For example, after Mg is doped, the p-GaN (P-type GaN) epitaxial material generated has a higher hole concentration. After Si is doped, the n-GaN (N-type GaN) epitaxial material generated has a higher electron concentration.

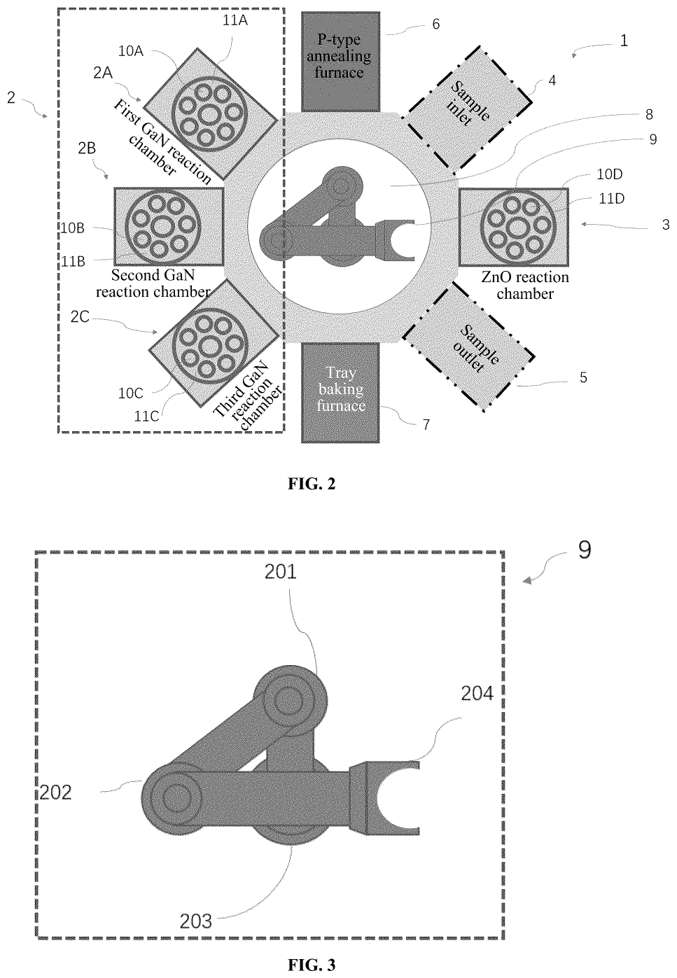

FIG. 2 is a schematic view of a combined epitaxial growth device for GaN and ZnO compounds in Embodiment 1. The device in FIG. 2 can be used to manufacture the GaN-based ZnO chip. The combined epitaxial growth device 1 having multiple reaction chambers shown in FIG. 2 includes GaN reaction chambers 2 (specifically including a first GaN reaction chamber 2A, a second GaN reaction chamber 2B and a third GaN reaction chamber 2C), a ZnO reaction chamber 3, a sample inlet 4, a sample outlet 5, a P-type annealing furnace 6, a graphite tray baking furnace 7, a feeding box 8, an actuator arm 9, a substrate 10 and a graphite tray 11. The first GaN reaction chamber 2A includes a substrate 10A and a graphite tray 11A. The second GaN reaction chamber 2B includes a substrate 10B and a graphite tray 11B. The third GaN reaction chamber 2C includes a substrate 10C and a graphite tray 11C.

FIG. 3 simply illustrates a schematic structural view of an actuator arm 9, including a joint 201, a joint 202, a joint 203 and a support handle 204. The joints 201, 202, 203 are controlled by a motor or a hydraulic device to rotate, such that the support handle 204 can move without a dead angle within a plane and support the graphite tray 11.

### Embodiment 1

A first MOCVD machine for producing a GaN epi-wafer and a second MOCVD machine for producing a ZnO thin film are used. Assuming that the GaN epi-wafer has growth time of 6 h and the ZnO thin film has growth time of 2.5 h (=preheating time 0.5 h+actual growth time 2 h of the ZnO thin film), there are 6/2.5=2.4 GaN reaction chambers, namely three GaN reaction chambers, and one ZnO reaction chamber. All reaction chambers are connected in production, as shown in FIG. 2.

The combined epitaxial growth in the embodiment is as follows:
1) The graphite tray 11 with the substrate 10 is placed into the sample inlet 4. An interface of the sample inlet 4 with the outside is closed, while an interface with the feeding box 8 is opened. The actuator arm 9 feeds the graphite tray 11 with the substrate 10 to the feeding box 8. The interface between the sample inlet 4 and the feeding box 8 is closed. Air in the feeding box 8 is extracted to create a vacuum environment. An interface between the first GaN reaction chamber 2A and the feeding box is opened. The actuator arm 9 feeds the graphite tray 11 with the substrate 10 to the first GaN reaction chamber 2A. The actuator arm 9 exits from the first GaN reaction chamber 2A. The first GaN reaction chamber 2A is sealed, and the vacuum environment is created.
2) The second graphite tray 11 with the substrate 10 is placed into the sample inlet 4. The interface of the sample inlet 4 with the outside is closed, while the interface with the feeding box 8 is opened. The actuator arm 9 feeds the graphite tray 11 with the substrate 10 to the feeding box 8. The interface between the sample inlet 4 and the feeding box 8 is closed. Air in the feeding box 8 is extracted to create the vacuum environment. An interface between the second GaN reaction chamber 2B and the feeding box is opened. The actuator arm 9 feeds the second graphite tray 11 with the substrate 10 to the second GaN reaction chamber 2B. The actuator arm 9 exits from the second GaN reaction chamber 2B. The second GaN reaction chamber 2B is sealed, and the vacuum environment is created.
3) The third graphite tray 11 with the substrate 10 is placed into the sample inlet 4. The interface of the sample inlet 4 with the outside is closed, while the interface with the feeding box 8 is opened. The actuator arm 9 feeds the graphite tray 11 with the substrate 10 to the feeding box 8. The interface between the sample inlet 4 and the feeding box 8 is closed. Air in the feeding box 8 is extracted to create the vacuum environment. An interface between the third GaN reaction chamber 2C and the feeding box is opened. The actuator arm 9 feeds the third graphite tray 11 with the substrate 10 to the third GaN reaction chamber 2C. The actuator arm 9 exits from the third GaN reaction chamber 2C. The third GaN reaction chamber 2C is sealed, and the vacuum environment is created.
4) A timing program is set. The GaN reaction chambers are started at a time interval of 2.5 h. The first GaN reaction chamber 2A is started, preheated and injected with the gas. The second reaction chamber 2B is started, preheated and injected with the gas after 2.5 h of preheating and gas injection of the first GaN reaction chamber 2A. The third reaction chamber 2C is started, preheated and injected with the gas after 5 h of preheating and gas injection of the first GaN reaction chamber 2A.

Specifically, upon completion of 6-h growth of the GaN epi-wafer in the first GaN reaction chamber 2A, the first GaN reaction chamber 2A is opened. The actuator arm 9 takes out the graphite tray 11 with the substrate 10 after the GaN epi-wafer is grown completely in the first GaN reaction chamber 2A. The first GaN reaction chamber 2A is sealed. The actuator arm 9 extracts the gas in the feeding box 8 to create the vacuum environment. The P-type annealing furnace 6 is opened. The actuator arm 9 feeds the graphite tray from the feeding box 8 to the P-type annealing furnace 6. The P-type annealing furnace 6 anneals the graphite tray 11, on which the GaN epi-wafer is grown completely, for 1 min (the reference time is 20 s to 3 min, and the annealing time can be adjusted according to the specific process). After the P-type annealing step on the graphite tray 11 on which the GaN epi-wafer is grown completely, the P-type annealing furnace 6 is opened, the actuator arm 9 takes out the previously fed graphite tray 11, and the P-type annealing furnace 6 is closed. Both the actuator arm 9 and the graphite tray 11 are located in the feeding box 8. The gas in the feeding box is extracted to create the vacuum environment. The interface between the ZnO reaction chamber 3 and the feeding box 8 is opened. The actuator arm 9 feeds the graphite tray 11 to the ZnO reaction chamber 3. The interface between the ZnO reaction chamber 3 and the feeding box 8 is closed. After 0.5 h upon completion of the growth on the graphite tray 11 with the substrate 10 in the first GaN reaction chamber 2A, the ZnO reaction chamber 3 starts to work, and the transparent ZnO electrode thin film is grown on the graphite tray 11 for 2 h (the reference time is 2-3 h and the growth time can be adjusted according to the specific process). Upon completion of the growth of the thin film, the interface between the ZnO reaction chamber 3 and the feeding box 8 is opened.

The actuator arm 9 takes out the graphite tray 11, the interface between the ZnO reaction chamber 3 and the feeding box 8 is closed, both the graphite tray 11 and the actuator arm 9 are located in the feeding box 8, and the gas in the feeding box 8 is extracted to create the vacuum environment. The sample outlet 5 is opened, the actuator arm 9 feeds the graphite tray to the sample outlet 5, the chip grown completely is taken out through the sample outlet 5 and fed to the outside, and the graphite tray 11 still remains on the actuator arm 9. After the finished chip is taken out, the actuator arm 9 brings the graphite tray 11 back to the feeding box 8. The graphite tray baking furnace 7 is opened, the actuator arm 9 feeds the graphite tray 11 to the graphite tray baking furnace 7, the actuator arm 9 returns to the feeding box 8, and the graphite tray baking furnace 7 is closed. The graphite tray baking furnace 7 is heated, until GaN and ZnO residues on the graphite tray 11 are vaporized. The graphite tray baking furnace 7 discharges vaporized gas, and the graphite tray 11 becomes clean again. The interface between the graphite tray baking furnace 7 and the feeding box 8 is opened, and the actuator arm 9 takes out the graphite tray 11. The graphite tray baking furnace 7 is closed, the sample inlet 4 is opened, and the actuator arm 9 feeds the graphite tray 11 to the sample inlet 7. The graphite tray 11 with the substrate 10 is replaced, the interface of the sample inlet 4 with the outside is closed, and the interface between the sample inlet 4 and the feeding box 8 is opened. The actuator arm 9 returns to the feeding box 8, the interface between the sample inlet and the feeding box 8 is closed, and the vacuum environment is created in the feeding box 8. The first GaN reaction chamber 2A is opened, the actuator arm 9 places the graphite tray 11 with the substrate 10 into the first GaN reaction chamber 2A, the actuator arm 9 exits from the first GaN reaction chamber 2A, and the first GaN reaction chamber 2A is sealed. Therefore, one circulation is completed in the first GaN reaction chamber 2A.

Upon completion of the first circulation, the first GaN reaction chamber 2A is preheated again at 500° C. after 1 h, and injected with the gas for second circulation. Subsequent circulation is executed at the time interval of 1 h.

After 2.5 h of the first circulation of the first GaN reaction chamber 2A, the second GaN reaction chamber 2B is preheated and injected with the gas. After 5 h of the first circulation of the first GaN reaction chamber 2A, the third GaN reaction chamber 2C is preheated and injected with the gas. Both the second GaN reaction chamber 2B and the third GaN reaction chamber 2C enter new circulation after 1 h upon completion of the reaction.

In first circulation, the ZnO reaction chamber 3 is preheated and injected with the gas for the first time after 0.5 h upon completion of the growth in the first GaN reaction chamber 2A, preheated and injected with the gas for the second time after 0.5 h upon completion of the growth in the second GaN reaction chamber 2B, and preheated and injected with the gas for the third time after 0.5 h upon completion of the growth in the third GaN reaction chamber 2C. After 2 h, the growth in the ZnO reaction chamber is completed. The actuator arm 9 takes out the graphite tray 11, both the actuator arm 9 and the graphite tray 11 are located in the feeding box 8, and the gas in the feeding box is extracted to create the vacuum environment. The interface between the sample outlet 5 and the feeding box 8 is opened, the actuator arm 9 feeds the graphite tray 11 to the sample outlet 5, the chip grown completely is taken out through the sample outlet 5 and fed to the outside, and the graphite tray 11 still remains on the actuator arm 9. After the finished chip is taken out, the actuator arm 9 brings the graphite tray 11 back to the feeding box 8. The graphite tray baking furnace 7 is opened, the actuator arm 9 feeds the graphite tray 11 to the graphite tray baking furnace 7, the actuator arm 9 returns to the feeding box 8, and the graphite tray baking furnace 7 is closed. The graphite tray baking furnace 7 is heated, until GaN and ZnO residues on the graphite tray 11 are vaporized. The graphite tray baking furnace 7 discharges vaporized gas, and the graphite tray 11 becomes clean again. The graphite tray baking furnace 7 is opened, and the actuator arm 9 takes out the graphite tray 11. The graphite tray baking furnace 7 is closed, the sample inlet 4 is opened, the actuator arm 9 feeds the graphite tray 11 to the sample inlet 7, and the actuator arm 9 returns to the feeding box 8, thereby completing the first circulation of the ZnO reaction chamber, and entering second circulation. With the manner in which the graphite tray is taken out and fed to the furnace automatically, the labor cost can be reduced effectively.

The annealing furnace 6 is intended to eliminate the residual stress of the GaN epi-wafer, reduce the deformation and cracking of the GaN epi-wafer, refine the granularity, regulate the structure and remove the structural defects. There are mainly two annealing processes at present, including furnace annealing in the GaN reaction chamber, and furnace annealing with the graphite tray taken out and placed into the separate annealing furnace. The latter is employed in the embodiment. Specifically, at 6 h when the GaN epi-wafer on the graphite tray 11 in the first GaN reaction chamber 2A is grown completely, the actuator arm 9 transfers the graphite tray to the annealing furnace 6 to anneal for 1 min (the reference time is 20 s to 3 min, and the annealing time can be adjusted according to the specific process). Upon completion of the annealing, the actuator arm 9 transfers the graphite tray 11 to the ZnO reaction chamber for next reaction. As an added component, the annealing furnace 6 may be removed if the MOCVD machine has the furnace annealing function. Therefore, FIG. 2 should not be taken as an inherent design form of the present disclosure, and any design with or without the annealing furnace at the interface should be included in the protection scope of the present disclosure.

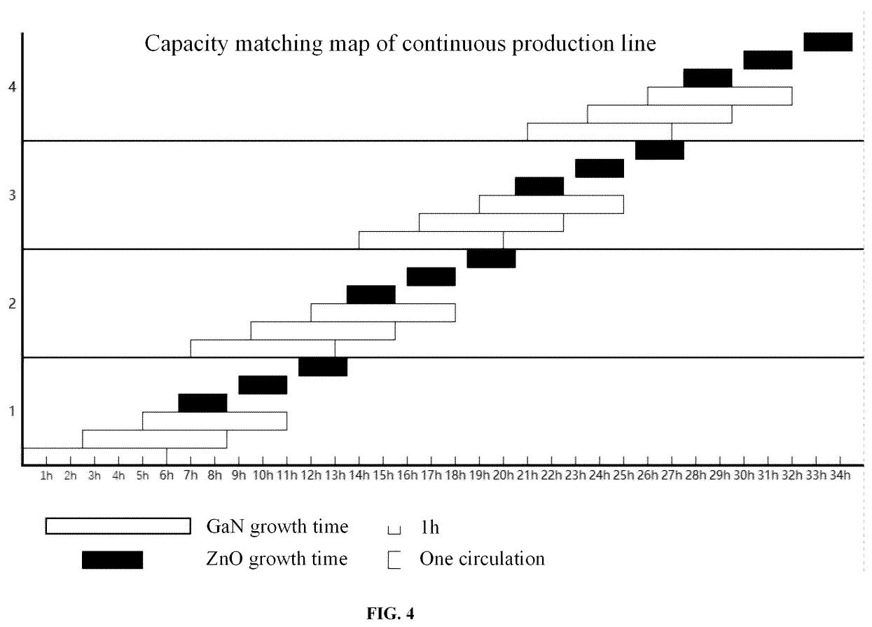

Specifically, as shown in FIG. 4, the GaN epi-wafer in the embodiment has growth time of 6 h, and the ZnO thin film has growth time of 2.5 h (=preheating time 0.5 h+actual growth time of the ZnO thin film 2h). The actuator arm 9 feeds the graphite tray 11 sequentially to the first GaN reaction chamber 2A, the second GaN reaction chamber 2B, and the third GaN reaction chamber 2C. Based on the growth of the GaN epi-wafer in the first GaN reaction chamber 2A, the second GaN reaction chamber 2B starts to grow the GaN epi-wafer after 2.5 h of the growth of the first GaN reaction chamber 2A, and the third GaN reaction chamber 2C starts to grow the GaN epi-wafer after 5 h of the growth of the first GaN reaction chamber 2A.

After 6 h, the GaN epi-wafer is grown completely in the first GaN reaction chamber 2A, and the actuator arm 9 feeds the graphite tray 11, on which the GaN epi-wafer is grown completely, to the ZnO reaction chamber 3. At 6.5 h, the ZnO reaction chamber 3 starts to grow the ZnO thin film on the graphite tray 11 fed from the first GaN reaction chamber 2A, and the growth of the ZnO thin film is completed at 8.5 h. At 9 h, the ZnO reaction chamber 3 starts to grow the ZnO thin film on the graphite tray 11 fed from the second reaction chamber 2B, and the growth of the ZnO thin film is completed at 11 h. At 11.5 h, the ZnO reaction chamber 3 starts to grow the ZnO thin film on the graphite tray 11 fed from the third reaction chamber 2C, and the growth of the ZnO thin film is completed at 13.5 h, thereby completing one circulation. Whether the production is continued is determined according to actual requirements (the production is stopped if the production quantity meets the standard, or otherwise, next circulation and production is continued).

In case of the continuous production, the chip in the ZnO reaction chamber 3 is removed, and the substrate 10 is respectively supplemented to the vacant GaN reaction chamber 2A, GaN reaction chamber 2B and GaN reaction chamber 2C, to enter next circulation and produce the finished chip products continuously.

For those of ordinary skilled in the art, certain simple modifications or substitutions may be made without departing from the concept of the present disclosure, which does not involve any inventive efforts. Therefore, simple improvements made to the present disclosure by those skilled in the art according to disclosures of the present disclosure should be included in the protection scope of the present disclosure. The above embodiments are preferred embodiments of the present disclosure. Any processes similar to the present disclosure and equivalent changes should be included in the protection scope of the present disclosure.

What is claimed is:

1. A combined epitaxial growth system having multiple reaction chambers, comprising:
a first growth device, wherein the first growth device is an metal-organic chemical vapor deposition (MOCVD) machine for preparing a group III-V compound, multiple group III-V compound reaction chambers are formed in the MOCVD machine, and the group III-V compound reaction chambers each are configured to prepare a group III-V compound epi-wafer;
a second growth device, wherein the second growth device is an MOCVD machine for preparing a group II-VI compound, a group II-VI compound reaction chamber is formed in the MOCVD machine, and the group II-VI compound reaction chamber is configured to prepare a group II-VI compound epi-wafer; and
a feeding device,
wherein the multiple group III-V compound reaction chambers are sequentially started in terms of a same time interval; and assuming that the time interval is a, a>0, the group III-V compound epi-wafer has growth time of x, x>0, and the group II-VI compound epi-wafer has growth time of y, y>0, there is a need to satisfy a=y.

2. The combined epitaxial growth system according to claim 1, wherein the second growth device is replaced with an MOCVD machine for preparing a group III-VI compound, and a group III-VI compound reaction chamber is formed in the MOCVD machine and configured to prepare a group III-VI compound epi-wafer.

3. The combined epitaxial growth system according to claim 1, wherein there is one group II-VI compound reaction chamber.

4. An operation method of the combined epitaxial growth system having multiple reaction chambers according to claim 1, wherein the operation method assumes that there are n group III-V compound reaction chambers, n being an integer greater than 0, and comprises the following steps:
1) preparing group III-VI compound epi-wafers: taking substrates, placing the substrates into the group III-V compound reaction chambers respectively, assuming that i has an initial value of 1, a value of the i being in a range of [1, n], starting an ith group III-V compound reaction chamber, and starting the ith group III-V compound reaction chamber after a period of at least (i−1)y, thereby obtaining group III-V compound epi-wafers on surfaces of the substrates in all of the group III-V compound reaction chambers;
2) starting the feeding device, increasing the value of the i by 1, and transferring a group III-V compound epi-wafer in the ith group III-V compound reaction chamber to the group II-VI compound reaction chamber in the second growth device after a period of at least x+(i−1)y;
3) preparing a chip: starting the group II-VI compound reaction chamber, and obtaining, after a period of at least x+iy, a chip with a group II-VI compound epi-wafer covering a surface of the group III-V compound epi-wafer;
4) removing the chip from the group II-VI compound reaction chamber, and supplementing a substrate to the vacant group III-V compound reaction chamber; and
5) going back to step 2) if inn, and setting the value of the i as 1 and going back to step 2) if i=n; or ending a reaction if group III-VI compound epi-wafers generated in remaining group III-V compound reaction chambers are all transferred to the group II-VI compound reaction chamber sequentially to obtain the chip.

5. The operation method according to claim 4, wherein the second growth device is replaced with an MOCVD machine for preparing a group III-VI compound, and a group III-VI compound reaction chamber is formed in the MOCVD machine and configured to prepare a group III-VI compound epi-wafer.

6. The operation method according to claim 4, wherein there is one group II-VI compound reaction chamber.

7. The operation method according to claim 4, wherein the number n of the group III-V compound reaction chambers, the x and the y satisfy: n=x/y if a value of x/y is a positive integer; and n=x/y and the value of the n is obtained by rounding up if the value of x/y is not the positive integer.

8. The operation method according to claim 5, wherein the number n of the group III-V compound reaction chambers, the x and the y satisfy: n=x/y if a value of x/y is a positive integer; and n=x/y and the value of the n is obtained by rounding up if the value of x/y is not the positive integer.

9. The operation method according to claim 6, wherein the number n of the group III-V compound reaction chambers, the x and the y satisfy: n=x/y if a value of x/y is a positive integer; and n=x/y and the value of the n is obtained by rounding up if the value of x/y is not the positive integer.

10. The operation method according to claim 4, wherein a tray is provided in each of the group II-VI compound reaction chamber and the group III-V compound reaction chamber; the tray is preferably a graphite tray; and the operation method further comprises an annealing step with furnace annealing and a P-type annealing furnace between step 1) and step 3), a step of preheating the group II-VI compound reaction chamber before starting the group II-VI compound reaction chamber in step 3), a step of baking the tray between step 3) and step 4), and a step of suspending operation between step 4) and step 5) for a period which is greater than 0 and is preferably 1 h.

11. The operation method according to claim 5, wherein a tray is provided in each of the group II-VI compound reaction chamber and the group III-V compound reaction chamber; the tray is preferably a graphite tray; and the operation method further comprises an annealing step with furnace annealing and a P-type annealing furnace between step 1) and step 3), a step of preheating the group II-VI compound reaction chamber before starting the group II-VI compound reaction chamber in step 3), a step of baking the tray between step 3) and step 4), and a step of suspending operation between step 4) and step 5) for a period which is greater than 0 and is preferably 1 h.

12. The operation method according to claim 6, wherein a tray is provided in each of the group II-VI compound reaction chamber and the group III-V compound reaction chamber; the tray is preferably a graphite tray; and the operation method further comprises an annealing step with furnace annealing and a P-type annealing furnace between step 1) and step 3), a step of preheating the group II-VI compound reaction chamber before starting the group II-VI compound reaction chamber in step 3), a step of baking the tray between step 3) and step 4), and a step of suspending operation between step 4) and step 5) for a period which is greater than 0 and is preferably 1 h.

13. A combined epitaxial growth device having multiple reaction chambers, comprising:
a first growth device, wherein the first growth device is a metal-organic chemical vapor deposition (MOCVD) machine for preparing a group III-V compound, and multiple group III-V compound reaction chambers are formed in the MOCVD machine and configured to prepare a group III-V compound epi-wafer respectively;
a second growth device, wherein the second growth device is an MOCVD machine for preparing a group II-VI compound, and a group II-VI compound reaction chamber is formed in the MOCVD machine and configured to prepare a group II-VI compound epi-wafer; and
a feeding device, wherein the feeding device is a feeding box, and an actuator arm is provided in the feeding device.
